(19) United States
(12) Patent Application Publication
(10) Pub. No.: US 2015/0031222 A1
(43) Pub. Date: Jan. 29, 2015

(54) ATTACHMENT CARD FOR SUBSCRIBER IDENTITY MODULE CARD AND METHOD FOR MANUFACTURING THE SAME

(71) Applicant: Mao Bang Electronic Co., Ltd., Taoyuan County (TW)

(72) Inventor: Ta-Lun SUNG, Taoyuan County (TW)

(21) Appl. No.: 14/338,057

(22) Filed: Jul. 22, 2014

(30) Foreign Application Priority Data
Jul. 23, 2013 (TW) 102126257

(51) Int. Cl. H05K 1/11; H05K 3/30

(52) U.S. Cl. CPC H05K 1/118; H05K 1/111; H05K 3/305
USPC 439/77; 29/831

(57) ABSTRACT

An attachment card for Subscriber Identity Module (SIM) cards and a method for manufacturing the same are revealed. The attachment card includes a flexible printed circuit board (FPC) and a chip. The chip is disposed on one surface of the FPC with a plurality of bumps, located at a central area among preset positions for formation of the bumps. The bumps are arranged according to the established specification. The method includes several steps. First arrange a chip at a central area of a FPC by surface mount technology. Then form a plurality of bumps on one surface of the FPC. Thereby the requirement of compact size is achieved. The manufacturing processes are also simplified. Thus the cost is reduced and the attachment card has more application.

### BACKGROUND OF THE INVENTION

The present invention relates to an attachment card for Subscriber Identity Module (SIM) cards and a method for manufacturing the same, especially to an attachment card for Subscriber Identity Module (SIM) cards and a method for manufacturing the same in which a chip is disposed on a central area among the preset positions for formation of the bumps on a flexible printed circuit board first. Then a plurality of bumps is formed at the preset positions. The bumps are used for electrical connection.

A Subscriber Identity Module (SIM) card is used in cell phones. The card holds personal information of the mobile phone's user including phone number, text messages, and other data. The SIM card is mainly operated on the Global System for Mobile Communications (GSM) network while it is also compatible for User Equipment (UE)/USIM (Universal Subscriber Identity Module) cards of Universal Mobile Telecommunications System (UMTS) and IDEN phones.

Along with the popularity of mobile phones, other integrated circuit card with various functions is used in combination with the SIM card. Not only the number of integrated circuit card users need to carry with them can be reduced, the integrated circuit card is also convenient to use by the equipment of the mobile phones such as mobile power. There is a plurality of cards available that can be used in combination with the SIM card such as debit card, ATM card (bank card), or credit card. While in use, the attachment card is directly attached to the SIM card of the mobile phone and is electrically connected to a plurality of contacts arranged according to the available specification so as to provide preset functions of the attachment card. Moreover, a general attachment card includes a printed circuit board (PCB) and a chip. A plurality of exposed contacts is disposed on one surface of the chip. The chip is electrically connected to and fixed on the PCB by the exposed contacts. A plurality of bumps for electrical connection is arranged at one surface of the PCB and is electrically connected to the contacts of the SIM card in a one to one correspondence manner. For example, the SIM cards available now include Mini SIM card (40a in FIG. 3), Micro SIM card (40b in FIG. 3), and Nano SIM card (40c in FIG. 3). The contacts in these SIM cards are arranged according to the established specifications. For example, there are 6 contacts (but not limited) arranged in a 2×3 pattern (as shown in FIG. 3). Thus the preset functions of the attachment card are provided due to connection between the SIM card the components inside the mobile phone (such as power) while the attachment card is attached to the SIM card.

However, the attachment card has following disadvantages during manufacturing processes and/or in use. First no matter the chip of the attachment card available now is electrically connected to and fixed on the PCB by wire bounding or SMT (Surface Mount Technology after standard package (such as Quad Flat Package (QFP)). Gold wire has loop height and molding thickness of the chip needs to be increased. Thus the thickness of the attachment card is increased. This doesn't meet the requirement of compact design. The design has negative effect on the combinations between the attachment card and the SIM card. For example, the thicker attachment card or the attachment card with larger size is unable or difficult to be attached to the SIM card in use. Especially when the SIM card available now has updated from Mini SIM card to Micro SIM card, and even Nano SIM card. It's getting difficult to use the attachment card in combination with the SIM card. Moreover, there is an additional molding process. The molding is used for protection of gold wire. But this leads to increasing in production cost of the attachment card and has negative effect on mass production and applications of the attachment card.

In order to overcome the above shortcomings, the present invention replaces PCB with flexible printed circuit board (FPC) and uses chip scale package (CSP) to avoid the additional molding process. And the chip is electrically connected to and fixed on the FPC by SMT. In practice, the inventor of the present invention found that the SMT process mentioned above has disadvantages. Refer to FIG. 9, when the chip is electrically connected to and fixed on the hump side of the FPC (disposed with a plurality of bumps). The bumps are electrically connected to a plurality of contacts arranged at the SIM card in a one to one correspondence manner. The manufacturing processes include following steps. First form a plurality of bumps 92 at one surface 91 of a FPC 90 by dimpling. According to the technique available now, there are 6 bumps 92 arranged at the surface 91 of the FPC 90 6 in a 2×3 pattern. Each bump 92 is electrically connected to one of the 6 contacts (as shown in FIG. 3) disposed on the SIM card according to the established specification. In FIG. 9, only two bumps 92 are shown. Then perform solder printing. A solder bump 93 is printed on the preset electrically connection points on the FPC 90 respectively. Next connect and fix the chip by SMT. At last, the surface of the bump side is filled with an underfill. That means adhesive is filled into a gap between the chip after treatment of SMT (not shown in the figure) and FPC 90 to improve the quality of surface adhesion between the chip and the FPC 90. However, in the above solder printing process, a stencil 95 disposed with a plurality of insertion holes 41 corresponding to electrically connection points on the FPC 90 is used and covered the surface 91 of the FPC 90. There are already a plurality of bumps 92 with a certain height (such as 300 μm) projecting upward from the surface 91. Thus the bottom of the stencil 95 is pressed over the bumps 92 first and is unable to attach to the surface 91 of the FPC 90 directly while the stencil 95 being pressed over the surface 91 of the FPC 90. This not only leads to deformation of the bumps 92 but also affects quality of the electrical connection between the bump 92 and the contact of the SIM card. Moreover, a gap 96 formed between the bottom surface of the stencil 94 and the surface 91 of the FPC 90 is increased due to the height (300 μm) of the bumps 92. This causes difficulty in control of the amount of solder paste in solder printing process. As shown in FIG. 9, the height of the solder bump 93 is larger than the height of the insertion hole 94 of the stencil 9. The difference therebetween is equal to the height of the gap 96 so that the amount of solder paste used is difficult to control. There is room for improvement.

### SUMMARY OF THE INVENTION

Therefore it is a primary object of the present invention to provide an attachment card for SIM cards and a method for manufacturing the same. The attachment card for SIM cards includes a flexible printed circuit board (FPC) and a chip with preset functions. A plurality of bumps for electrical connection is disposed on a surface of the FPC. Each bump is electrically connected to one of a plurality of contacts on the SIM card in a one to one correspondence manner and the contacts are arranged according to the established specification. Thus the functions of the attachment card are provided by the SIM card while the attachment card is attached to the SIM card. The chip is arranged at the same surface of the FPC as the bumps. The chip is located at a central area among the bumps arranged according to the established specification. Thereby the attachment card meets the requirements of thinner design and miniature size so as to have wider applications.

It is another object of the present invention to provide a method for manufacturing an attachment card for SIM cards that includes a plurality of steps as follows. Step 1: Provide a flexible printed circuit (FPC) board according to the size of a SIM card and the FPC is attached to the SIM card while in use. One surface of the FPC is preset with a plurality of positions for formation of a plurality of bumps. The bumps are electrically connected to a plurality of contacts arranged at the SIM card in a one to one correspondence manner. A central area is formed among the preset positions for formation of the bumps. Step 2: arrange a chip at a central area formed among preset positions for formation of the bumps by surface mounting technology (SMT). Step 3: form a plurality of bumps at the surface of the FPC with the chip by dimpling and the chip is located at a central area among the bumps formed. Therefore the attachment card produced has compact size and wider applications. The manufacturing processes of the attachment card are also simplified so that the cost is reduced.

### BRIEF DESCRIPTION OF THE DRAWINGS

FIG. 1 is a schematic drawing showing a cross sectional view of an embodiment according to the present invention;

FIG. 2 is a schematic drawing showing an enlarged top view of a flexible printed circuit (FPC) board of the embodiment in FIG. 1 according to the present invention;

FIG. 3 is a schematic drawing showing a top view of a chip of an embodiment according to the present invention compared with a Mini SIM card, a Micro SIM card, a Nano SIM;

FIG. 4 is a schematic drawing showing a cross sectional view of a chip of an embodiment treated by Chip Size Package (CSP) and connected to a FPC by surface mounting technology (SMT) according to the present invention;

FIG. 5 as a schematic drawing showing a cross sectional view of an embodiment used in combination with a SIM card according to the present invention;

FIG. 6 is a schematic drawing showing a cross sectional view of an embodiment with a card holder used in combination with a SIM card according to the present invention;

FIG. 7 is a schematic drawing showing a cross sectional view of the embodiment in FIG. 6 being mounted into a SIM card slot according to the present invention;

FIG. 8 is a schematic drawing showing a cross sectional view of a stencil being pressed over a flexible printed circuit board for performing solder printing before formation of a plurality of bumps on the FPC during manufacturing processes of an embodiment according to the present invention;

FIG. 9 is a schematic drawing showing a cross sectional view of a stencil being pressed over a flexible printed circuit board for performing solder printing after formation of a plurality of bumps on the FPC during conventional manufacturing processes.

### DETAILED DESCRIPTION OF THE PREFERRED EMBODIMENTS

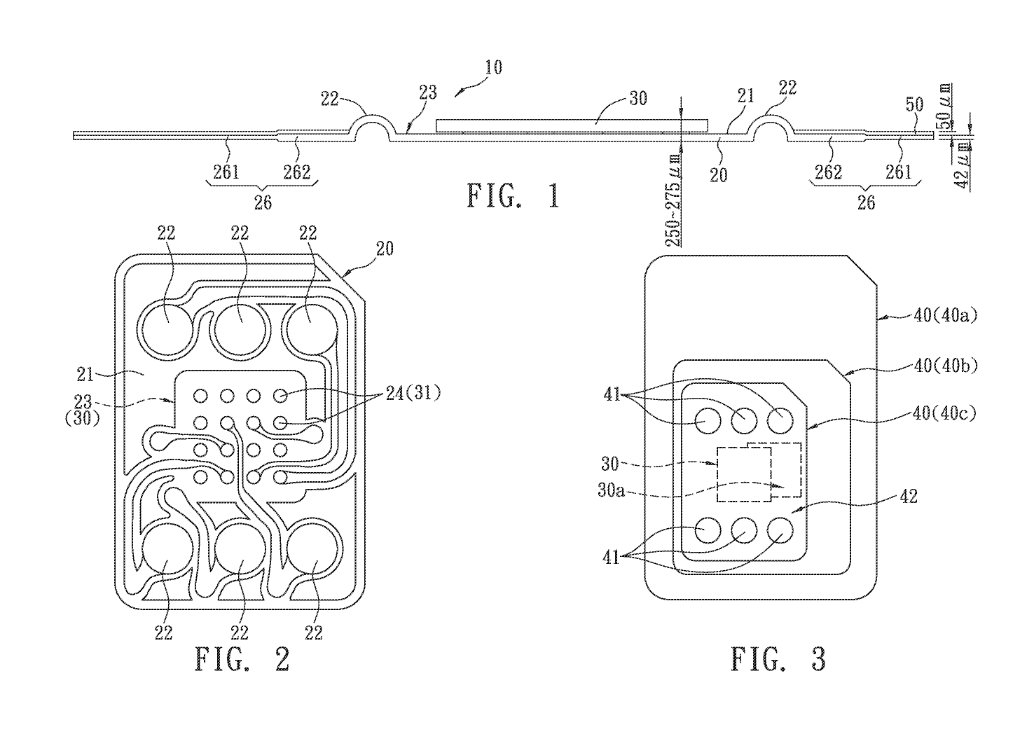

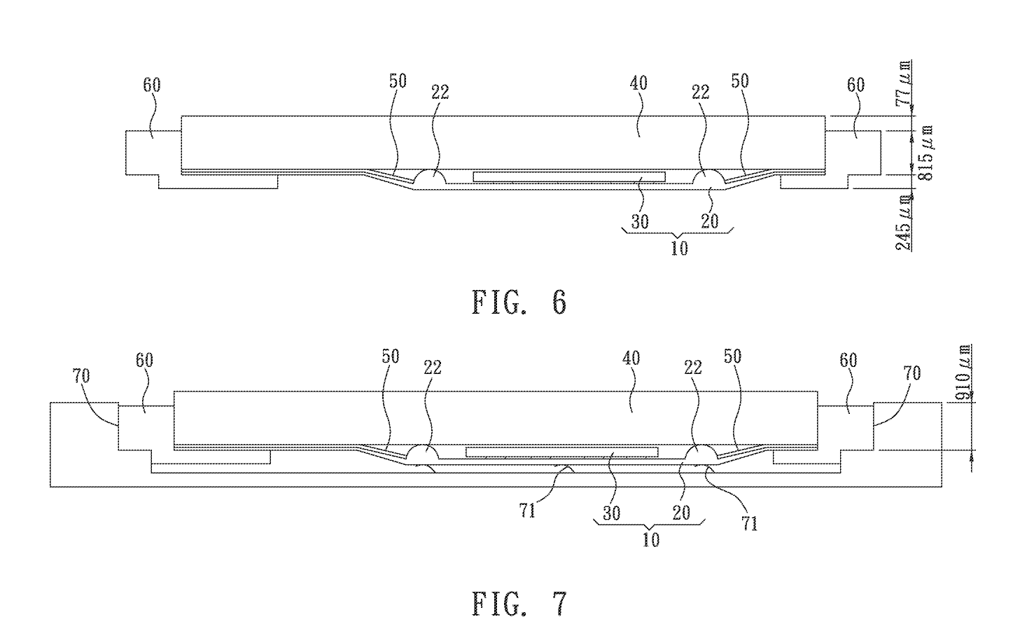

Refer to FIG. 1, FIG. 2 and FIG. 3, an attachment card 10 for SIM cards of the present invention includes a flexible printed circuit (FPC) board 20 and a chip 30 with preset functions. A surface 21 of the FPC 20 is disposed with a plurality of bumps 22 for electrical connection. Each bump 22 is corresponding to and electrically connected to one of a plurality of contacts 41 on a SIM card 40 used (as shown in FIG. 3) in a one to one correspondence manner. Refer to FIG. 5, FIG. 6 and FIG. 7, the attachment card 10 is attached to the SIM card 40 while in use. Thus various functions of the attachment card 10 preset according to user's needs such as debit card, ATM card (bank card), or credit card can be used. The chip 30 is arranged at the surface 21, the same surface the bump 22 disposed on. The bumps 22 are arranged according to the established specifications and the chip 30 is in a central area 23 among the bumps 22. Thereby the attachment car 10 meets the requirement of compact design and has more applications.

Refer to FIG. 2 and FIG. 3, the functions of the SIM card are expanding rapidly while the size is more compact and the weight is lighter. For example, refer to FIG. 3, a Mini SIM card 40a with larger size is revealed. A smaller Micro SIM card 40b is an upgrade from the Mini SIM card 40a. A Nano SIM 40c is even thinner and smaller than the Micro SIM card 40b. As to the arrangement of the multiple contacts 41 of the SIM card available now, the contacts 41 are disposed on the SIM card 40 (40a, 40b, 40c) at specific positions according an established arrangement. As shown in FIG. 3, there are (but not limited to) 6 contacts arranged in a 2×3 pattern (2 rows, 3 columns). A central area 42 is formed between the third contact 41 in the first row and the third contact 41 in the second row. As mentioned before, the six bumps 22 (as shown in FIG. 2) disposed on the surface 21 of the FPC 20 of the present invention are electrically connected to the six contacts 41 arranged at the SIM card 40 used (as shown in FIG. 3) in a one to one correspondence manner. Thus there is also a central area 23 (as shown in FIG. 1 and FIG. 2) formed between the third bump 22 in the first row and the third bump 22 in the second row. The chip 30 is connected to the FPC 20 correspondingly and fixed on the central area 23 of the FPC 20, as shown in FIG. 1 and FIG. 2.

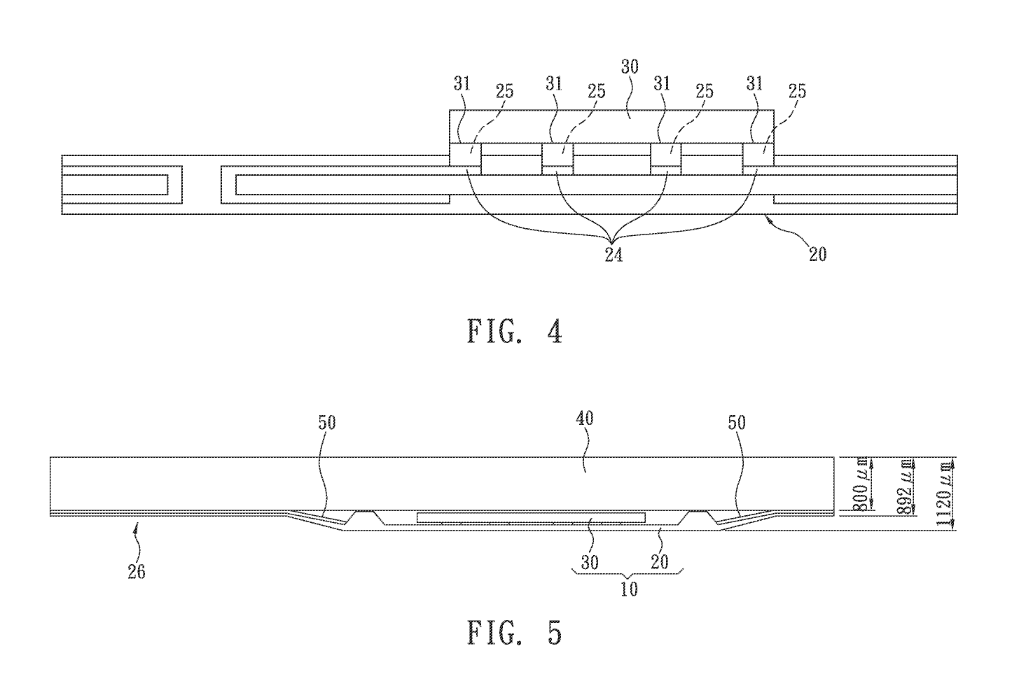

Refer to FIG. 4, the production of the chip 30 of the present invention has used Chip Size Package (CSP) technology. The chip 30 is electrically connected to and fixed on the FPC 20 by surface mounting technology (SMT). A plurality of electrical contact points 24 is preset on the FPC 20 according to design requirements. As shown in FIG. 2, there are sixteen (4×4) electrical contact points 24. In FIG. 4, there are (but not limited to) only four electrical contact points 24 shown in the figure. Then a solder bump 25 is formed on each electrical contact point 24 by printing according to design requirements for surface mounting the chip 30. That means the chip 30 is connected to and fixed on the FPC 20 by SMT and a plurality of exposed pads 31 (there are sixteen in FIG. 2) on the chip 30 is electrically connected to the electrical contact points 24 on the FPC 20 in a one to one correspondence manner. The sixteen (4×4) electrical contact points 24 on the FPC 20 are not restricted to be arranged at the center of the central area 23, as shown in FIG. 1 and FIG. 2. They can be also disposed on the non-central area of the central area 23, as 30a shown in FIG. 3.

Refer to FIG. 5, a peripheral area 26 of the FPC 20 of the attachment card 10 is attached to the SIM card 40 firmly by an adhesive layer 50. As shown in FIG. 1, the adhesive layer 50 is made from (but not limited to) an adhesive of 3M company with the thickness of about 50 μm. The area of the adhesive layer 50 can be extended to the area the SIM card attached, the same size as the surface area of the SIM card 40, as shown in FIG. 5. As to the thickness of the peripheral area 26, the thickness of the peripheral area 26 is about 42 μm if the peripheral area 26 is a peripheral area without circuit 261. Once the peripheral area 26 is a peripheral area arranged with circuit 262, the thickness of the peripheral area 26 is about 90 μm.

Moreover, the size of each component of the attachment card 10 shown in FIG. 1 is as follows. The total height of the bump 22 (measured from the bottom surface of the FPC 20) is 300 μm. The thickness of the chip 30 is 175 μm. The thickness of the adhesive layer 50 is 50 μm. The total height of the chip 30 (measured from the bottom surface of the FPC 20) is ranging from 250 μm to 275 μm. The thickness of the area with circuit (such as the peripheral area with circuit 262) on the FPC 20 is 90 μm while the thickness of the area without circuit (such as the peripheral area without circuit 261) on the FPC 20 is 42 μm. Thus there is a certain distance/space—25 μm (300−275=25) between the top surface of the chip 30 and the top of the bump 22. While the attachment card 10 of the present invention is used together with a SIM card 40, the size of each component can be controlled as the sizes shown in FIG. 5. The thickness of the SIM card 40 is 800 μm. The total thickness of the SIM card 40 adhered to the area of the FPC 20 without circuit such as the peripheral area without circuit 261 is 892 μm. The total thickness of the SIM card 40 adhered to the area of the FPC 20 with circuit such as the peripheral area arranged with circuit 262 is 1120 μm, Thus it is learned that the size of the attachment card 10 of the present invention used together with a SIM card 40 is controlled in an acceptable range that meets the requirements of thin and compact design. The applications of the attachment card 10 are further increased.

Refer to FIG. 6, a further embodiment is revealed. The difference between this embodiment and the embodiment in FIG. 5 is in that the attachment card 10 is set into a card holder 60 after being fixed on and attached to the SIM card 40. In practice, the upper edge on the surface of the SIM card 40 is about 77 μm higher than the top surface of the card holder 60. This has no effect on original functions of the SIM card 40.

Refer to FIG. 7, the attachment car 10 is mounted into a SIM card slot 70 after being fixed on the SIM card 40 and set into the card holder 60. At least one spring 71 is arranged at an inner bottom surface of the SIM card slot 70. In FIG. 7, there are (but not limited to) three springs 71 used for upward and elastically supporting certain positions on the bottom surface of the FPC 20 of the attachment card 10. While in use, the upper edge on the surface of the SIM card 40 is about 20 μm lower than the top surface of the SIM card slot 70. This has no effect on original functions of the SIM card 40.

A method for manufacturing an attachment card 10 of the present invention includes a plurality of steps as follows.

Step 1: Providing a flexible printed circuit (FPC) board 20 and a chip 30 according to the size of a SIM card 40. The FPC 20 and the chip 30 are attached to the SIM card 40 to be used. A surface 21 of the FPC 20 is arranged with a plurality of preset positions for forming a plurality of bumps 22. After being formed on the preset positions, the bumps 22 are electrically connected to the contacts 41 on the SIM card 40 respectively. A central area 23 is formed among the preset positions.

Step 2: Fixing the chip 30 on and electrically connecting the chip 30 to the central area 23 of the FPC 20 by Surface Mount Technology (SMT).

Step 3: Forming the plurality of bumps 22 on the preset positions so as to make the chip 30 locate at the central area 23 among the bumps 22. Thus an attachment card 10 including the FPC 20 and the chip 30 is produced.

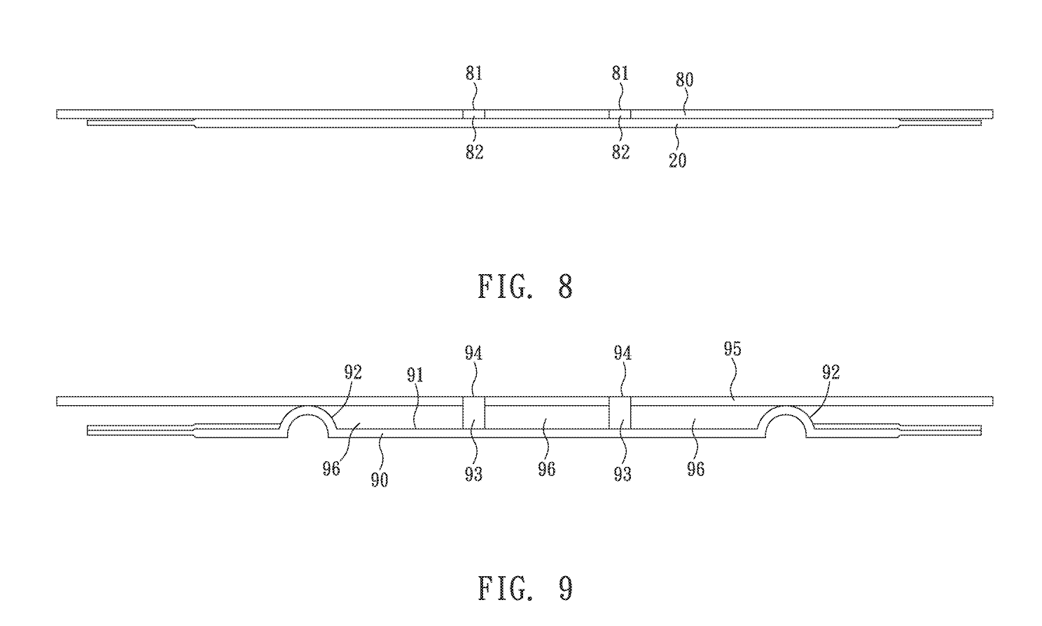

Refer to FIG. 1, in the attachment card 10, there is a 25 μm distance (300−275=25) between the top surface of the chip 30 and the top of the bump 22. That means the height of the chip 30 is a bit lower than the height of the bump 22. And the chip 30 is arranged at the central area 23 among the plurality of bumps 22. While performing solder printing processes mentioned above (as shown in FIG. 9), a plurality of problems including difficulty in control of the amount of solder and easy deformation of the bump mentioned above occurs. Yet during the manufacturing processes of the attachment card 10 of the present invention, first the chip 30 used is electrically connected to and fixed on central area 23 of the FPC 20 by SMT in the step 2. Then the formation of the bumps 22 is performed in the step 3. Refer to FIG. 8, while perform g solder printing process during manufacturing of the attachment card 10, a stencil 80 with a plurality of preset insertion holes 81 corresponding to electrical contact points 24 on the FPC 20 is covered on the surface of the FPC 20 for performing solder printing. At the moment, the projecting bumps 22 with a certain height such as 300 μm has not formed on the surface of the FPC 20 yet. Thus the stencil 80 can be pressed tightly over the surface of the FPC 20, as shown in FIG. 8. Therefore the amount of solder paste used in the solder printing for forming bumps 82 can be controlled effectively. The problems of conventional solder printing processes mentioned above can be solved.

In summary, the conventional manufacturing processes are as follows. First perform dimpling of the FPC. The next step is solder printing. Then fix and electrically connect the chip onto the surface of the FPC that is corresponding to the chip by surface mounting technology (SMT). Next the surface is filled with an underfill. As to a method for manufacturing an attachment card of the present invention, it includes a plurality of processes as follows. In the beginning, solder printing is carried out on a FPC. Then the chip is electrically connected and fixed onto the surface of the FPC that is corresponding to the chip by SMT. The next step is applied an underfill. Finally, pattern the FPC with dimples.

Compared with conventional technique the attachment card and the method for manufacturing the same of the present invention has following advantages. The height is thinner and the volume is minimized. The manufacturing processes are simplified and the cost is reduced. Moreover, the attachment card has more applications such as use in combination with Nano SIM card (as shown in FIG. 3).

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. An attachment card for a subscriber identity module (SIM) card having a plurality of contacts for electrical connection comprising a flexible printed circuit board and a chip; wherein
one surface of the flexible printed circuit board is disposed with a plurality of bumps for electrical connection; the bumps are arranged according to an established specification the contacts of the SIM card being disposed so as to electrically connect to the contacts of the SIM card in a one to one correspondence manner; a central area is formed among the bumps and lower than the bumps;
the chip with preset functions is electorally connected to and fixed on the surface of the flexible printed circuit board with the bumps by surface mount technology (SMT), located at the central area among the bumps arranged according to the established specification;
wherein the attachment card is attached to the SIM card while in use and the bumps of the flexible printed circuit board are electrically connected to the contacts of the SIM card in the one to one correspondence manner; this the preset functions of the attachment card are provided by the SIM card.

2. The device as claimed in claim 1, wherein the SIM card includes Mini SIM card, Micro SIM card, and Nano SIM card.

3. The device as claimed in claim 1, wherein the lumber of the contacts of the SIM card being disposed is six and the contacts are disposed in a 2×3 pattern while the flexible printed circuit board is disposed with six bumps in the same 2×3 pattern; thus the bumps are electrically connected to the contacts in a one to one correspondence manner; the central area is formed among the six bumps and lower than the six bumps.

4. The device as claimed in claim 1, wherein when the chip with preset functions is electorally connected to and fixed on the surface of the flexible printed circuit board with the bumps and located at the central area among the bumps arranged according to the established specification, a distance between a top surface of the chip and a top of the bump is about 25 μm.

5. The device as claimed in claim 1, wherein a peripheral area of the FPC around the chip is attached to the SIM card firmly by an adhesive layer.

6. The device as claimed in claim 5, wherein the adhesive layer is able to extend to or near a periphery of the SIM card.

7. The device as claimed in claim 1, wherein the attachment card and the SIM card is set into a card holder after the attachment card being fixed on and attached to the SIM card; the attachment card and the SIM card are clipped and held in the card holder.

8. The device as claimed in claim 1, wherein an underfill is applied to a gap between the chip and the flexible printed circuit board for improvement of adhesion quality between the chip and the surface of the flexible printed circuit.

9. A method for manufacturing an attachment card for a subscriber identity module (SIM) card comprising the steps of:
Step 1: providing a flexible printed circuit (FPC) board and a chip according to a SIM card so that the FPC and the chip are attached to the SIM card to be used; wherein one surface of the FPC is arranged with a plurality of preset positions where a plurality of bumps for electrical connection is formed; after being formed on the preset positions, the bumps are electrically connected to contacts on the SIM card correspondingly and a central area is formed among the preset positions and the central area is lower than the bumps.
Step 2: electrically connecting the chip to and fixing the chip on the central area 2 of the FPC by surface mount technology (SMT);
Step 3: forming the bumps on the preset positions so as to make the chip locate at the central area among the bumps and lower than the bumps; thus an attachment card including the FPC and the chip is produced.

10. The method as claimed in claim 9, wherein the step 2 further includes a step of solder printing in which a stencil is tightly pressed over the surface of the FPC for performing solder printing so as to form a solder bump used for electrical connection on each of the preset positions of the bumps.

11. The method as claimed in claim 8, wherein the method further includes a step of applying an underfill between the step 2 and the step 3; the step of applying an underfill is to apply adhesive into a gap between the chip and the FPC after the chip being electrically connected to and fixed on the central area of the FPC by surface mount technology so as to improve quality of surface adhesion between the chip and the FPC.
